(19) United States
(12) Patent Application Publication
(10) Pub. No.: US 2006/0154489 A1
(43) Pub. Date: Jul. 13, 2006

(54) Semiconductor base structure for molecular electronics and molecular electronic-based biosensor devices and a method for producing such a semiconductor base structure

(75) Inventors: Marc Uwe Tornow, Garching (DE); Gerhard Abstreiter, Garching (DE); Shozo Fujita, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: Fujitsu Limited, Kawasaki (JP)

(21) Appl. No.: 10/530,870

(22) PCT Filed: Oct. 10, 2003
(86) PCT No.: PCT/EP03/11221

§ 371 Date: Jan. 13, 2006

(30) Foreign Application Priority Data
Oct. 12, 2002 (DE) 102 47 679.9

(51) Int. Cl. H01L 21/302

(52) U.S. Cl. 438/745

(57) ABSTRACT

The invention concerns a structured semiconductor surface as basis for molecular electronics or molecular electronics-based bio-sensors. The starting point is a heterostructure consisting of two undoped layers of a semiconductor material that are separated by an extremely thin (a few nm) layer of a different semiconductor material. This material stack is cleaved perpendicular to the layer planes and the middle layer is selectively etched. Source- and drain contacts for conductive organic “wires” are by built by evaporation with a thin metal film. The middle conductive layer can be employed as electrostatic gate. An assembly for contacting a few up to single wires can be obtained by two sequential separations and evaporations. Possible organic wires are e.g. molecules with conjugated (E-electron system, DNA-oligonucleotides or carbon nanotubes. By means of a further functionalisation with receptors for biomolecular recognition (antibodies, proteins) an employment as highly sensitive biosensor for detection, analysis and quantification of special biomolecules and their mutual interaction becomes possible (e.g. DNA-protein interaction).

### 1. SUBJECT OF THE INVENTION

The invention refers to a semiconductor base structure for molecular electronics and molecular electronics-based biosensor applications and a method for producing such a structure.

### 2. STATUS OF TECHNOLOGY

Various approaches for molecular electronics (ME) have been reported in the literature. More recent ones include conductance studies through single conjugated molecules (M. A. Reed et al., Science 1999, J. Reichert et al., Phys. Rev. Lett. 2002) or through whole monolayers embedded between Au electrodes near a silicon gate electrode (J. H. Schön et al., Nature 2001). The electrode fabrication either relies on metal break junction techniques where the electrode distance has to be adjusted to the molecules' length or on metal deposition (evaporation) onto a previously prepared molecule monolayer. Currently used or proposed techniques for biomolecule (in particular protein) detection, analysis, quantification or interaction studies include publications and patents about, e.g., classical two-dimensional gel electrophoresis, micro-capillary electrokinetic separation techniques with fluorescent readout, micro-array analogs to DNA (MacBeath G. and Schreiber S L, Science 2000), plasmon-resonance, quartz microbalance, silicon structures based capacitive setups (Berggren et al., Electroanalysis 2001), light addressable potentiometric sensors (George et al., Sensors and Acuators, 2000), Silicon FETs (Schöning and Luth, 2001, Cloarec et al., Sensors and Acuators, 1999, Snow et al. US2002012937), mechanical strain based detection using Si cantilevers (Fritz et al., Science, 2000) or functionalized, chemically deposited Si nanostructures (Cui et al., Science 2001). In a recently filed patent application some of the present inventors propose the use of functionalized, highly sensitive sub-μm size lateral field effect transistors based on Silicon-on-Insulator (SOI) technology (G. Abstreiter, A. R. Bausch, K. Buchholz, S. Luber, M. G. Nikolaides, S. Rauschenbach, E. Sackmann, M. Tornow: Silicon-on-Insulator biosensor device, Germany, DPA 102 21 799.8, April 2002).

Employing electrochemistry based ME for biosensor applications was recently demonstrated by E. M. Boon, J. E. Salas, J. K. Barton, Nature Biotechnology, Volume 20, Page 282, 2002. A pure ME approach however, where the sensing organic wire is connected to solid electrodes on both ends is not known to the authors.

### 3. TECHNICAL PROBLEMS OR DISADVANTAGES TO BE SOLVED BY THE INVENTION

In most presently used schemes investigating ME the metal electrodes are connected to the organic nano-wire after it has been formed and positioned. Either a top electrode is being deposited on top of a monolayer film of molecules. This procedure carries the risk of damaging the sensitive film by creating pin-holes, defects or incorporating metal particles as clusters into it. It may either destroy the device (short circuit) or easily give rise to artifacts such as tunneling phenomena through metal islands rather than molecular wires. In the other main approach of using break junctions the electrode distance has to be adjusted dynamically to the molecule length according to the current-voltage characteristics monitored in parallel. In addition to the elaborate setup which cannot be easily integrated into an array on a chip scale the finally obtained distance is not absolutely known but only concluded indirectly from the measured conductance.

The opposite approach of first preparing the miniaturized electrode design, on which the molecular wires then can attach has been limited to relatively long molecules such as DNA or carbon nanotubes (group of C. Dekker, T U Delft, C. F. J. Tans et al., Volume 386, Page 474, 1997) due to the limitations of advanced lithographic techniques such as, e.g., electron beam lithography which can merely produce structures less than a few ten nm.

Biomolecular interactions have been studied by various label-bound techniques proving the binding reaction between specific molecule partners. The direct impact of the binding reaction onto the electronic configuration of the involved reactants however may become accessible by the described method of measuring the conductance of one of the molecules in real-time during its binding reaction to an analyte molecule.

It is the problem underlying the invention to find a semiconductor base structure according to the preamble of claim 1 which does not have the disadvantages mentioned and to find a method for producing such a semiconductor base structure according to claim 5.

### 4. SOLUTION

The underlying problem is solved for a semiconductor base structure by the features of claim 1, especially in connection with the subclaims 2 to 10 and by a method for producing such a semiconductor base structure according to claim 11, especially in connection with claims 12 to 14.

### 5. DETAILED DESCRIPTION OF THE INVENTION

The proposed semiconductor base structure for molecular electronics (ME) and ME-based biosensor applications comprises a patterned semiconductor heterostructure surface forming the source, drain and gate contacts to build up electronic devices such as transistors from conductive organic “wires” (such as organic molecules with conjugated π-electron system, DNA oligonucleotides, carbon nanotubes). By eventually further functionalizing the organic wire of this hybrid system with, e.g., receptors for biomolecular recognition such as antibodies or proteins the device can be employed as highly sensitive electrical biosensor for the detection, analysis and quantification of specific biomolecules and their mutual interaction, e.g., DNA-protein interaction.

Starting point for the device basis preparation is a semiconductor heterostructure which can be epitaxially grown by molecular beam epitaxy (MBE) and consists of two thick (typically several hundred nm) undoped layers of material “A” separated by an extremely thin (few nm) doped conductive layer of different semiconductor material “B”, or of different composition in case of compound semiconductors. This material stack is being cleaved perpendicular to the layer planes and the obtained cleavage plane is subsequently selectively etched such that only the central thin layer “B” is removed a few nm deep into the cleavage plane. Finally, a thin (few nm) metal layer is deposited on the etched cleavage plane to form conductive source and drain electrodes on top of material “A” in such way that those are separated only by the very short, groove-like “nano-gap”.

The active region to be bridged by the wires may be reduced to a few square-nm by again cleaving the heterostructure perpendicular to the first direction before selective etching. The latter will be followed then by a two step metal evaporation from different directions such that the area of minimal electrodes distance is located exactly at the structure's corner. As illustrated in FIG. 3, the side wall metallization on the opposite sides of the groove only here face each other. Forming the ME device out of this base structure is achieved by connecting the source and drain contact with organic wires. These wires may consist of (semi-) conductive, typically chain-like (bio-) molecules of lengths just fitting to bridge the short gap. Depending of the sample's base structure many thousands molecules in parallel will contribute, or just a few, eventually one single wire, can be addressed thereby maximizing the detection sensitivity. The chosen wire species has to be terminated by chemical endgroups able to covalently bind to the metal electrodes (e.g., a thiol (—SH) group forming a S—Au bond in the case of gold or gold containing alloy electrodes). Molecule deposition may be achieved by self-assembly techniques from solution or solid source evaporation in ultra-high vacuum. These processes will in general result in an entire coverage of the metal planes with attached molecules the majority of which however is neither contributing to nor disturbing the device's performance. The source-drain current is only carried by the small fraction of molecules bridging the gap between source and drain. The conductivity may be electrostatically controlled by the conductive thin layer “B” at the bottom of the groove by operating it with an electric bias voltage versus source or drain, in analogy to standard field effect transistors (FETs).

Selective binding of a bio-molecular analyte to the organic wire, either directly in the case of protein-DNA binding or via the wire's functionalization with specific receptor sites, may modify its delocalized electron distribution. This in turn should directly lead to a change in molecular conductance thus allowing its application as a sensitive bio sensor or to investigate basic molecular binding kinetics in detail and real-time.

### 6. MAIN PURPOSE OF INVENTION

The described heterostructure semiconductor structure serves as a basis for the fabrication of a ME device such as a triple lead system (transistor). With unparalleled precision and flexibility the electrodes distance and active area to be bridged by the conductive organic wires (conjugated organic molecules, DNA, carbon nanotubes, . . . ) can be engineered on the nm-scale. This specifically includes distances of the order of a few nanometers which are of particular importance to investigate a whole class of short (1-3 nm) organic conjugated molecules as, e.g., oligophenyls. This distance regime is not accessible by state-of-the-art lithographic techniques. By furnishing the organic wire with specific functionality (receptor molecule sub-units) the resulting hybrid structure can be employed as a sensitive detector for biomolecules or as a direct tool to study specific biomolecular interactions.

### 7. MAIN NOVELTY

The described device base structure enables the extremely precise preparation of the contact scheme needed to employ short (few nm length) wire-like organic molecules for ME and ME based, bio-sensing applications. Ultra-narrowly spaced electrodes are inherently combined with the functionality of an embedded gate to tune the molecule conductivity by the electrostatic field effect. The high precision and reproducibility is based on a) the starting semiconductor multi layer structure which can be tailored with atomic monolayer precision, b) the (sequentially twice) single crystal cleavage of the stack which eventually forms atomically flat and sharp cleavage planes and corners, c) the selective wet etching which can exceed selectivity ratios of the order of 1:100 and d) the (sequential) deposition of smooth metal contact layers of expected surface roughness ≈11 nm.

Building on this ME concept the wire system may be further functionalized with specific receptor units for the selective capturing of biomolecules. The binding reaction is expected to change the molecules conductivity turning the hybrid device into a biosensor device.

### 8. SHORT DESCRIPTION OF THE FIGURES

FIG. 1: Device basis fabrication. a) Semiconductor heterostructure stack A/B/A; crystallographic cleavage, b) Cross-section, after selective etching and angular metal evaporation

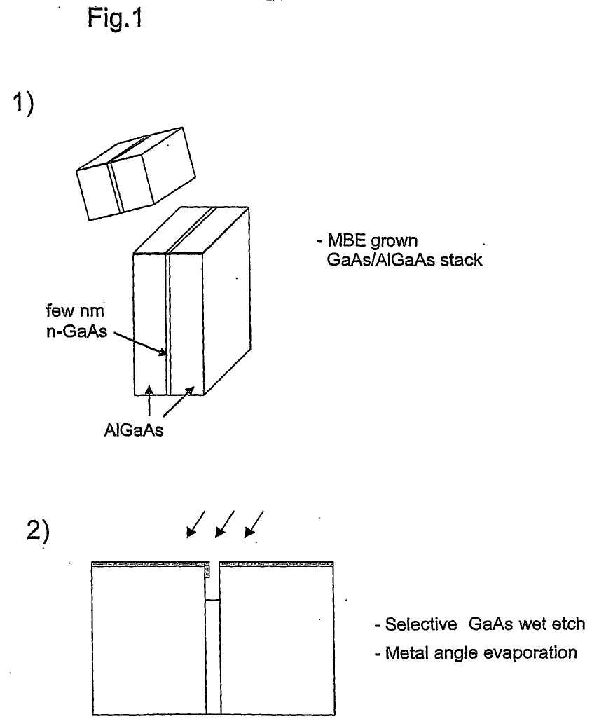

FIG. 2: Device operation set-up. a) Conjugated molecules (example dithiolbiphenyls) bridging the electrode gap; transistor operation set-up. b) Immobilized molecules with specific biomolecular binding group (e.g., DNA nucleotide) for biosensing.

FIG. 3: Few (single) molecule configuration. Corner of heterostructure after two perpendicular cleavages and two sequential angular evaporations. Dashed area marks region of minimal electrodes distance.

FIG. 4: Contacts scheme. Exemplary device (cross-section) with lithographically defined contacts to external electrical wiring/set-up (see section 9.)

### 9. EXAMPLE FOR DEVICE REALIZATION

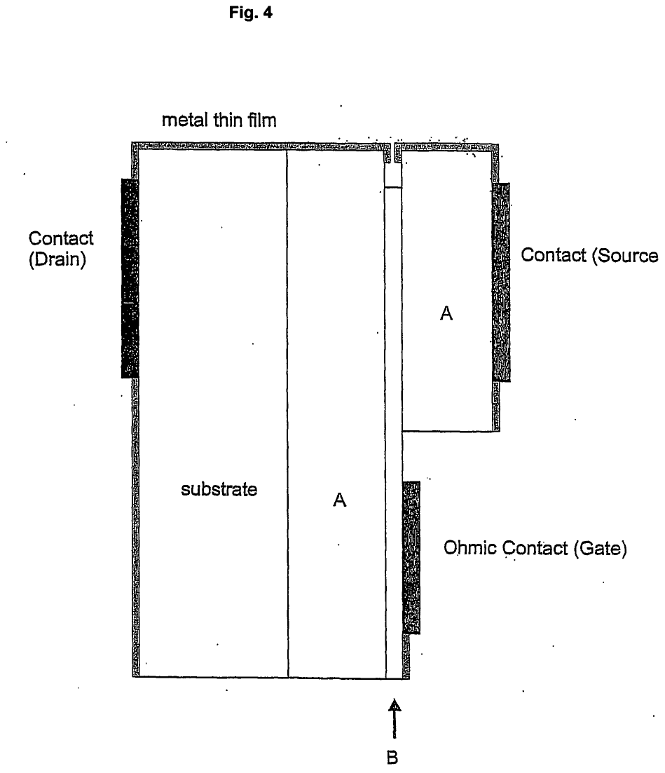

For the basic electrode fabrication, all material heterostructures are suited which allow at the same time fabrication with monolayer thickness precision, atomically sharp cleavage along (two perpendicular) crystal directions and highest selective etching. In the following, the fabrication process is outlined for the example of a GaAs/AlGaAs heterostructure. In this case, the stack may comprise an undoped AlGaAs layer (thickness 300 nm), a highly n-doped (Si 10¹⁸ cm⁻³) GaAs layer (5 nm) and a second undoped AlGaAs layer (300 nm), all grown on top of a standard semi-insulating GaAs <100> substrate (650 μm) by MBE. For proof of principle a sample piece of a few mm² area is cut from the grown wafer. Before any cleaving all needed large electrical contact pads (order of 100 μm) connecting to outer wiring/setup will be manufactured by means of standard resolution photolithography, etching and metallization. As sketched in FIG. 4 the contacts for source and drain may be deposited on the back and front surface of the wafer, the gate contact onto an step-like structure on the front side etched closely down to the n-doped GaAs layer. Source and drain contact metals may consist of TiAu. For the gate contact an ohmic contact scheme as, e.g., alloyed NiGeAu is best suited to ensure at least shallow migration of the metal inside the semiconductor for reliably contacting the doped GaAs layer. Source and drain contacts will be connected to their respective thin-film metal layers (forming the actual molecule source and drain) directly through the later evaporation of the latter. By this, one avoids the critical procedure to apply macroscopic contacts onto the narrow cleaved plane.

As a next step the sample is cleaved mechanically along a <110> crystallographic direction. The exact position of cleavage has to be previously defined by a short surface groove at the sample edge, well outside the supposed electrically active region. The AlGaAs/GaAs stack splits perfectly along an atomically flat plane. In the following the thin GaAs at the obtained cleavage plane is selectively wet etched against AlₓGa₁₋ₓAs up to a depth of about 10 nm (reported maximum selectivity 120:1 for x=0.3 with a recipe consisting of citric acid/H₂O₂, Ref. G. C. DeSalvo et al., JECS 1992). Finally, the source and drain contact metallization is established by thermal or electron beam metal evaporation of about 4 nm thickness in ultra high vacuum (UHV). Here, evaporation from an angle ensures that no short circuit between the electrodes is obtained and that the highly doped GaAs film remains isolated from the metal. For the given example numbers of 5 nm GaAs and 4 nm nominal metal deposition one obtains a resulting gap width of ˜2 nm for a 45° evaporation. A suitable metal system to obtain a superior surface smoothness (≈nm) together with good adhesion properties is a Palladium-Gold (PdAu) alloy of composition 20:80.

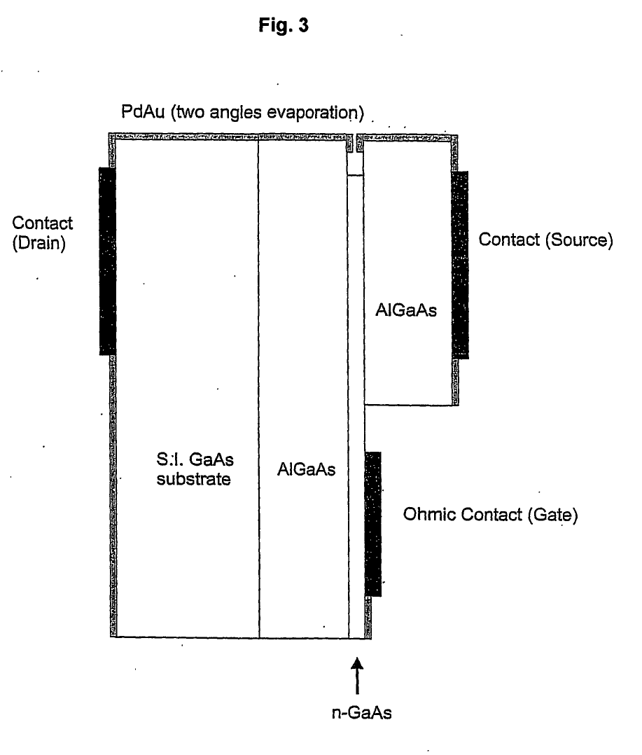

In case of the proposed few (eventually single) molecule device preparation the heterostructure sample first has to be cleaved twice, along two perpendicular crystal directions. After selective etching two metal thin film evaporations follow, from different angular directions (see FIG. 3) such that exactly and only at the corner of the two cleavage planes the side wall metallization on the two opposite sides of the groove face each other. Here, on a minimal area of typically a few nm² the source and drain contacts take their lowest distance.

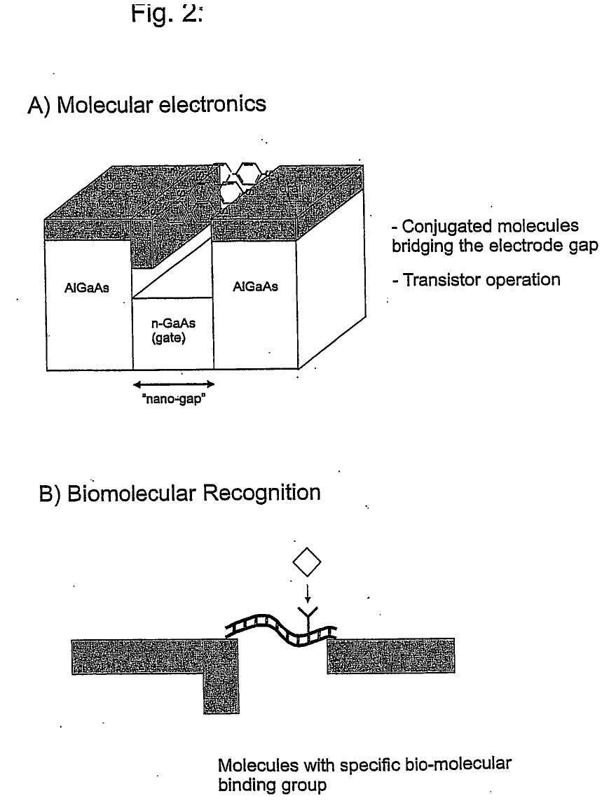

Following the described device basis fabrication the respective organic molecule nanowires can be deposited. Examples are Dithiol-oligophenyls (terminated on both sides with thiol-groups, compare FIG. 2 for the case of biphenyls) which can be self-assembled from solvent solution (ethanol). Other possible wires are highly charged species like double-stranded DNA oligonucleotides which will be deposited from aqueous, eventually electrolyte, solution. With respect to molecule deposition from aqueous solution the need for passiviation of AlGaAs against oxidation/dissolution is currently under investigation.

After having assembled parallel oriented wires finally bridging and covering the whole gap, the conductance between source and drain as a function of gate-voltage will be measured. When operating the device as a biosensor under physiologic buffer solutions such as to investigate the specific binding of proteins to DNA strands the question of needed PdAu electrode passivation (against the aqueous solution) will have to be addressed.

1. Semiconductor base structure for molecular electronics and molecular electronics-based biosensor applications, comprising a patterned semiconductor heterostructure surface forming the source, drain and gate contacts to build up hybrid electronic devices from this semiconductor base structure and one or more conductive organic wires.

2. Semiconductor base structure according to claim 1, wherein the organic wires are organic molecules with conjugated π-electron system, DNA oligonucleotides or car-bon nanotubes.

3. Semiconductor base structure according to claim 1, wherein the one or more organic wires of this hybrid system are further functionalized with receptors for biomolecular recognition or receptors made of biomolecules which recognize bioactive molecules like hormones, polysaccharides, lipids, or drugs such that the device can be employed as highly sensitive electrical biosensor for the detection, analysis and quantification of specific biomolecules and their mutual interaction.

4. Semiconductor base structure according to claim 3, wherein the receptors for biomolecular recognition are antibodies or proteins.

5. Semiconductor base structure according to claim 1, wherein a semiconductor heterostructure which consists of a material stack of two thick undoped layers of material A separated by an extremely thin doped layer of different thin semiconductor material B or of different composition in case of compound semiconductors, with conductive source and drain electrodes on top of material A which are separated only by a very short, groove-like nano-gap.

6. Semiconductor base structure as in claim 5, wherein the thin, selectively etched layer fulfils the function of a field effect gate electrode when operating the hybrid electronic device as a molecular electronics or biosensing device.

7. Semiconductor base structure as in claim 1, wherein the wires may consist of molecules of length fitting or exceeding the gap and being terminated and chemical endgroups able to covalently bind to the metal electrodes.

8. Semiconductor base structure as in claim 3, wherein a selective binding of a bio-molecular analyte to the organic nanowire changes the receptor's electron affinity towards the wire thus modifying its delocalized electron distribution and in turn leads to a change in molecular conductance.

9. Semiconductor base structure as in claim 5 wherein the heterostructure material stack comprises undoped AlGaAs for the thick layers and doped GaAs for the thin middle layer.

10. Semiconductor base structure as in claim 5, wherein the deposited metal is an alloy of Pd and Au.

11. A method of producing a semiconductor base structure according to claim 5, wherein the material stack being cleaved perpendicular to the layer planes and the obtained cleavage plane being subsequently selectively etched such that only the central thin layer B is removed deep into the cleavage plane and a thin metal layer being deposited on the etched cleavage plane from an angle to form the conductive source and drain electrodes.

12. A method for producing a semiconductor base structure according to claim 11, wherein the described cleavage is performed twice along different preferably perpendicular crystal directions and that two metal layers are being deposited sequentially from different angular directions in such way that a region of minimal electrodes distance forms exactly and only at the corner of the two cleavage claims.

13. A method for producing a semiconductor base structure according to claim 11, wherein the semiconductor heterostructure is epitaxially grown by molecular beam epitaxy (MBE).

14. A method for producing a semiconductor base structure for molecular electronics and molecular electronics-based biosensor applications according to claim 11, wherein the wire are being deposited by self-assembly techniques from solution or solid source evaporation in ultra-high vacuum, said semiconductor base structure comprising a patterned semiconductor heterostructure surface forming the source, drain and gate contacts to build up hybrid electronic devices from this semiconductor base structure and one or more conductive organic wires, in that the wires may consist of molecules of length fitting or exceeding the gap and being terminated and chemical endgroups able to covalently bend to the metal electrodes.
